(19) United States
(12) Patent Application Publication
(10) Pub. No.: US 2026/0293360 A1
(43) Pub. Date: Sep. 24, 2026

(54) OPTOELECTRONIC DEVICE AND METHOD FOR GENERATING A SEQUENCE OF RANDOM NUMBERS

(71) Applicant: AMS-OSRAM AG, Premstaetten (AT)

(72) Inventor: Dacoda NELSON, Hillsboro, OR (US)

(21) Appl. No.: 19/475,438

(22) PCT Filed: Jun. 6, 2024
(86) PCT No.: PCT/EP2024/065511

§ 371 Date: Oct. 15, 2025

Related U.S. Application Data
(60) Provisional application No. 63/521,429, filed on Jun. 16, 2023.

(51) Int. Cl. H10F 55/255; B82Y 20/00; G06F 7/58; H10F 77/00; H10F 77/30; H10F 77/40

(52) U.S. Cl. CPC H10F 55/255; G06F 7/588; H10F 77/334; H10F 77/496; H10F 77/953; B82Y 20/00

(57) ABSTRACT

An optoelectronic device for generating a sequence of random numbers is provided, which includes an emitter configured to emit pulses of primary electromagnetic radiation during operation, a conversion layer configured to absorb the primary electromagnetic radiation and to emit secondary electromagnetic radiation in response to the absorption, a receiver configured to receive the secondary electromagnetic radiation, and a controller coupled to the receiver, the controller being configured to evaluate with each pulse of primary electromagnetic radiation whether an amount of secondary electromagnetic radiation received by the receiver exceeds a predetermined threshold value and to append a number associated with a result of the evaluation to the sequence of random numbers. Further, an optoelectronic system and a method of generating a sequence of random numbers is provided.

### CROSS-REFERENCE TO RELATED APPLICATIONS

This application is a national phase of International Application No. PCT/EP2024/065511 filed on Jun. 6, 2024, which claims priority to U.S. Provisional Patent Application No. 63/521,429, which was filed on Jun. 16, 2023, the entire contents of both of which are incorporated herein by reference.

### FIELD OF THE INVENTION

An optoelectronic device for generating a sequence of random numbers is specified herein. Further, an optoelectronic system and a method of generating a sequence of random numbers is provided.

### BACKGROUND OF THE INVENTION

A random number generator, RNG, is a device or algorithm that generates a sequence of numbers that lack any discernible pattern or predictability. Random numbers are essential in many fields, including cryptography, computational modelling and/or simulations, and statistical analysis.

Quantum random number generators, QRNGs, are a type of RNG that utilize the principles of quantum mechanics to generate truly random numbers. Unlike classical RNGs that rely on deterministic algorithms or physical processes, QRNGs exploit the inherent randomness found at the quantum level.

QRNGs typically rely on the unpredictable nature of quantum phenomena, such as the behavior of photons or the measurement of quantum states. The key advantage of QRNGs is their ability to provide genuine randomness, as quantum mechanics introduces fundamental randomness into the process. This makes them suitable for applications where high-quality random numbers are crucial, such as cryptography and secure communication. QRNGs are also resistant to various forms of attacks, including those based on mathematical algorithms or physical observations. However, QRNGs can be more complex and challenging to implement than classical RNGs. They may require specialized hardware, often based on quantum optics or solid-state devices, to generate and measure the quantum states accurately. Additionally, QRNGs may have limitations in terms of speed and efficiency compared to classical RNGs.

### SUMMARY OF THE INVENTION

At least one objective of certain embodiments is to specify an optoelectronic device, which provides a small, low-power source of random numbers provided at high bandwidth and low latency.

This objective is achieved by the subject-matter according to the independent claims. Advantageous embodiments and developments of the optoelectronic device are given in the dependent claims and are also disclosed by the following description and the drawings.

According to an embodiment, an optoelectronic device for generating a sequence of random numbers comprises an emitter configured to emit pulses of primary electromagnetic radiation during operation.

Electromagnetic radiation may be called “light” in the following. The emitter is, for example, a component that generates electromagnetic radiation in the wavelength range between infrared radiation and UV radiation. In particular, the emitter can be configured to generate electromagnetic radiation in the wavelength range from at least 350 nm to at most 1100 nm, in particular in the wavelength range from at least 380 nm to at most 480 nm, during operation. For example, the emitter can be configured to generate electromagnetic radiation at a wavelength of 450 nm.

The emitter may comprise at least one surface emitter. In the present context, a surface emitter is understood to be a radiation-emitting component which emits the electromagnetic radiation generated during operation transversely, in particular perpendicularly, to a mounting surface on which the radiation-emitting component is mounted. However, it is also possible that the emitter comprises at least one edge emitter. This can mean that the emitter emits the electromagnetic radiation laterally, in particular parallel to a mounting surface on which the emitter is mounted. In particular, the emitter may be a semiconductor device comprising an epitaxially grown semiconductor body. In case of a surface emitter, the direction in which the electromagnetic radiation is then emitted during operation may be parallel to a growth direction of the semiconductor body. The semiconductor body may, for example, be based on semiconductor materials such as In(Ga)N, In(Ga)AlP, (Al)GaAs, (In)GaAs. The emitter may be, for example, a light emitting diode, LED, or a laser diode, in particular a superluminescent diode, a vertical-cavity surface-emitting laser, VCSEL, or an edge emitting laser, EEL. The emitter is configured to emit pulses of primary electromagnetic radiation. This can mean that the emitter is operated in a pulsed mode. In case of a laser diode, the duration of each pulse is, for example, at least 5 ns and at most 25 ns. Alternatively, the pulse duration is at least 10 ns and at most 20 ns. In case of an LED, the duration of each pulse is, for example, at least 50 ns and at most 100 ns, in particular at least 60 ns and at most 90 ns.

According to an embodiment, the optoelectronic device further comprises a conversion layer configured to absorb the primary electromagnetic radiation and to emit secondary electromagnetic radiation in response to the absorption.

The conversion layer may comprise a luminescent material. This can mean that a conversion of primary electromagnetic radiation into secondary electromagnetic radiation is due to luminescence, in particular photoluminescence, occurring in the conversion layer. Luminescence is a phenomenon where a physical system absorbs external energy, enters an excited state, and subsequently emits photons as it returns to its ground state. In the present case, the external energy is provided to the conversion layer via photons of primary electromagnetic radiation. The photons emitted by the conversion layer, i.e. photons of secondary electromagnetic radiation, may be lower in energy than the previously absorbed photons of primary electromagnetic radiation, i.e. the secondary electromagnetic radiation may have larger wavelengths than the primary electromagnetic radiation. This can mean that the wavelength range of the primary electromagnetic radiation do not overlap with the wavelength range of the secondary electromagnetic radiation. The primary electromagnetic radiation may be different from the secondary electromagnetic radiation. For example, the secondary electromagnetic radiation has a wavelength in the range from at least 600 nm to at most 700 nm. After absorbing the primary electromagnetic radiation, the luminescent material remains in an excited state for a specific duration, commonly known as photoluminescence lifetime. Quantum mechanics dictates that the lifetime is relatively short due to the rapid occurrence of light emission, which is considered “allowed” according to quantum rules. In other words, each pulse of the emitter produces a number of photons of primary electromagnetic radiation which travel through the conversion layer. A certain number of these photons will be absorbed by the conversion layer and converted into an electron-hole pair. After some time the electron and hole will recombine either radiatively (the emission of a new photon of secondary electromagnetic radiation with an energy characteristic to the electronic bandgap of the luminescent material) or non-radiatively (e.g. thermal processes).

According to an embodiment, the optoelectronic device further comprises a receiver configured to receive the secondary electromagnetic radiation.

The receiver may be called detector or photodetector in the following. The receiver may comprise at least one photodiode, for example. The receiver is configured in particular to receive at least part of the secondary electromagnetic radiation emitted by the conversion layer during operation. In particular, the receiver can be tuned to the conversion layer in such a way that the receiver has a particularly high absorption for the secondary electromagnetic radiation generated by the conversion layer. This can mean that the at least one photodiode comprised by the receiver has a bandgap energy that is smaller than the photon energy corresponding to the wavelength of the emitted secondary electromagnetic radiation. Further, the receiver may be tuned to preferably not absorb the primary electromagnetic radiation emitted by the emitter. This can mean that primary electromagnetic radiation is blocked from entering the detector, for example by means of a low-pass filter with a cutoff above the energy of the secondary electromagnetic radiation but below the energy of the primary electromagnetic radiation. The receiver (e.g. photodiode) may comprise a semiconductor body having at least one detecting layer adapted to absorb electromagnetic radiation generated by the conversion layer during operation and to convert it into electrical energy. The receiver may be formed, for example, in the same material system as the emitter or in a different material system.

According to an embodiment, the optoelectronic device further comprises a controller coupled to the receiver, the controller being configured to evaluate with each pulse of primary electromagnetic radiation whether an amount of secondary electromagnetic radiation received by the receiver exceeds a predetermined threshold value.

The controller may be implemented as control circuit. The controller is electrically connected to the receiver, e.g. via electrical interconnections. The controller and the receiver may be arranged on or in a common substrate. That the controller evaluates the amount of secondary electromagnetic radiation can mean that it counts the number of photons received by the receiver and compares that number with a predetermined threshold number. It can further mean that the controller determines an output voltage or output current of the receiver and compares that voltage/current with a predetermined threshold voltage/current. The predetermined threshold value may be stored in a storage device comprised by the controller. The predetermined threshold value may be determined by calibration prior to normal operation of the optoelectronic device. An example of determining the threshold value is explained below.

In an embodiment, the controller is further configured to append a number associated with a result of the evaluation to the sequence of random numbers.

As described below, the result of the evaluation whether the amount of secondary electromagnetic radiation received by the receiver exceeds the predetermined threshold value is based on randomness. Thus, the result forms a random result. On the one hand, the result can be “TRUE” (i.e. “1”), if the amount of secondary electromagnetic radiation received by the receiver exceeds the predetermined threshold value. On the other hand, the result can be “FALSE” (i.e. “0”), if the amount of secondary electromagnetic radiation received by the receiver does not exceed the predetermined threshold value. In other words, the controller may append “O” or “1” to the sequence of random numbers. Previous numbers of the sequence of random numbers are determined by evaluation of the amount of secondary electromagnetic radiation in response to previous pulses of primary electromagnetic radiation. This means that each pulse of primary electromagnetic radiation results in a new number in the sequence of random numbers.

According to an embodiment, an optoelectronic device for generating a sequence of random numbers comprises an emitter configured to emit pulses of primary electromagnetic radiation during operation, a conversion layer configured to absorb the primary electromagnetic radiation and to emit secondary electromagnetic radiation in response to the absorption, a receiver configured to receive the secondary electromagnetic radiation, and a controller coupled to the receiver, the controller being configured to evaluate with each pulse of primary electromagnetic radiation whether an amount of secondary electromagnetic radiation received by the receiver exceeds a predetermined threshold value and to append a number associated with a result of the evaluation to the sequence of random numbers.

The optoelectronic device described here is based on the following considerations, among others.

The emitter, e.g. an LED or laser-diode, can be switched on and off in a rapid, periodic manner in order to produce pulses of primary electromagnetic radiation. Each on/off cycle of the emitter produces a number of photons which travel through the conversion layer comprising a luminescent material. A certain number of these photons will be absorbed by the conversion layer, their characteristic energy converted into an electron-hole pair. After some time the electron and hole will recombine either radiatively (the emission of a new photon of an energy characteristic to the electronic bandgap of the material) or non-radiatively (thermal processes), wherein the manner of recombination is a source of randomness. The amount of time required for the recombination process to occur is an inherently random value (within a range of probable values) for each electron-hole pair. Additionally, the direction of the emitted photon of secondary electromagnetic radiation is inherently random. Because not every emitted photon will reach the receiver this also provides a source of randomness in the exact number of photons which reach the receiver. By knowing the characteristics of the emitter, the conversion layer, and the receiver, as well as the geometry of their placement in relation to each other, it is possible to determine a probabilistic range of photons which will reach the receiver during each cycle. A threshold value within this range is selected for the receiver. If this threshold is reached within the cycle the optoelectronic device produces a TRUE signal; if it is not, a FALSE signal is generated.

Thus, the optoelectronic device can be used to generate a sequence of random numbers. The optoelectronic device therefore forms a random number generator, in particular a quantum random number generator as the inherent randomness found at a quantum level is exploited.

The emitter, the conversion layer, the receiver and the controller can be arranged in a very compact way, so that, if adequately miniaturized, it fits in an extremely small package. Further, the emitter can be pulsed in a rapid, periodic manner. The emitter, the receiver and the controller can be based on standard semiconductor manufacturing techniques, and these components do not require high power consumption. Thus, a source of true randomness with very high bandwidth and a tiny form-factor with extremely low power consumption can be provided. Precise counting of photon numbers is not required. Further, complicated equipment and processes are not required.

According to an embodiment of the optoelectronic device, the conversion layer comprises a quantum dot material.

In this context, quantum dot materials are a class of semiconductor materials composed of nanoscale crystals. These crystals typically have diameters on the order of a few nanometers and consist of a specific number of atoms arranged in a regular pattern. The properties of quantum dots are determined by their size, shape, and chemical composition. The absorption spectrum of quantum dots can be tuned to absorb radiation of defined wavelengths by appropriately selecting their material, material composition, size and shape. Quantum dots exhibit quantum mechanical effects due to their small size and limited dimensionality, commonly referred to as quantum confinement. These effects include energy level quantization and discretization of electronic states. Quantum dots have a high luminescence quantum yield. They can be designed to produce the desired radiative emission of a photon instead of dispersing the absorbed photon's energy through other non-radiative processes, making them superior to other materials. This makes them attractive for applications in optoelectronics. Quantum dots can absorb and emit a wide range of light because their absorption and emission spectra can be controlled by dot size and chemical composition. This allows for the production of tailored quantum dots for specific applications. Therefore, the conversion layer can be tuned to absorb primary electromagnetic radiation emitted by the emitter and can be tuned to emit secondary electromagnetic radiation to be received by the receiver. Moreover, quantum dots exhibit high photochemical stability, meaning they have a low tendency to form defects or degrade under light exposure. This makes them suitable for use in durable optoelectronic devices.

The lifetime, i.e. the time period in which an electron-hole pair within the quantum dot material recombines, is inherently random on a per-quantum-dot basis. For a group of quantum dots, the number of quantum dots in an excited state at a time t after the illumination phase with primary electromagnetic radiation, assuming that 100% of the quantum dots, QD, are excited at every pulse of primary electromagnetic radiation, is given by

$$n ( t ) = N {e}^{- {β}_{rad} \cdot t} ,$$

where N is the total number of QDs and β_{rad} is the radiative rate, a measurable characteristic of QDs. Because not all QDs will be excited during the emitter pulse, not all excited QDs will emit a photon during recombination, and because those photons emitted by each QD travel in a random direction, the number of photons at the receiver will vary from pulse to pulse. The probabilistic spread between minimum and maximum photons counted per pulse can determined by the properties of the components and QDs. If the threshold value is selected within this range, random signals can be generated.

According to an embodiment of the optoelectronic device, the conversion layer comprises semiconductor nanocrystals.

This can mean that the conversion layer comprises a nanomaterial. In the following, the term “nanomaterial” is meant to include any material comprising nanoparticles. The nanomaterial can especially comprise nanodots, nanorods, nanowires, quantum dots, quantum rods or any combination thereof. For example, the conversion layer comprises a material of the group consisting of PbS, PbSe, ZnS, ZnSe, CdSe, CdTe, InAs, GaAs, InP, InGaP, GaP, CdS, or any combination thereof. Advantageously, semiconductor materials can be used for the conversion layer which are also used for the manufacturing of the emitter and/or the receiver. Further, nanomaterials, in particular semiconductor nanocrystals, can easily be mixed with polymers, glues and other organic substances that are used to form housings of packages or injection-molded covers. For example, the conversion layer forms a cover for the emitter or an emitter module. The QDs/semiconductor nanocrystals can be dispensed in optical silicone to form the cover. Alternatively, the conversion layer is deposited on an inner side of a package, in which the optoelectronic device is arranged.

According to an embodiment, the optoelectronic device further comprises a filter layer being arranged between the conversion layer and the receiver, wherein the filter layer is configured to block electromagnetic radiation apart from at least a portion of the secondary electromagnetic radiation.

This means that photons emitted by the emitter can be rejected by a filter layer placed between the conversion layer and the receiver; the filter can be such that it rejects photons of all energies emitted by the emitter and allows photons of the energies emitted by the conversion layer to pass. Some percentage of the photons emitted by the conversion layer during each on/off phase of the emitter will pass through the filter and strike the receiver/photodetector. The filter layer may form a cut-off filter. In particular, the filter layer may form a low-pass filter that only passes signals below its cutoff frequency while attenuating all signals above it. In this way, the high energy primary electromagnetic radiation emitted by the emitter is prevented from reaching the receiver. The filter layer may also form a band-pass filter, such that only wavelengths of the secondary electromagnetic radiation can pass the filter layer and reach the receiver. The filter layer may be formed by one or more dielectric, conducting and/or semiconducting layers, which are arranged in a stack.

The filter layer may be arranged on or above the receiver. Because only secondary electromagnetic radiation can reach the receiver, a measurement is more accurate and the primary radiation cannot falsify the measurement result. Thus, the generation of random numbers is not biased. The filter layer may not or only slightly deflect the secondary electromagnetic radiation, so that the generation of random numbers is not affected or biased.

According to an embodiment, the emitter comprises at least one light emitting diode, LED, or at least one laser diode.

As mentioned above, the at least one LED or laser diode may be based on semiconductor materials. The emitter can comprise more than one LED or laser diode. For example, the emitter comprises an array of LEDs and/or laser diodes. LEDs and laser diodes offer several advantages: they are highly energy-efficient. They convert a high percentage of electrical energy into light, minimizing energy wastage. This efficiency translates to reduced energy consumption. LEDS and laser diodes are inexpensive to manufacture and have a long operational lifespan. This longevity reduces the need for frequent replacements, saving both maintenance costs and resources. LEDs and laser diodes can be switched on and off rapidly, making them suitable for applications that require high-speed modulation and fast response times. LEDs and laser didoes are small in size and come in various form factors, making them easily integrable into various devices and systems. They can be miniaturized and used in applications where space is limited. Further, they offer a wide range of wavelengths of electromagnetic radiation to be emitted. Thus, the emitter can be tuned to the absorbance of the conversion layer or vice versa. In particular, the emission spectrum of the emitter can be matched with the first exciton peak of the conversion layer. Moreover, in the present application it is advantageous that the emitter exhibits a narrow wavelength range. With such tight emission spectrum it is possible to easily block the primary electromagnetic radiation before reaching the receiver, e.g. by means of the filter layer, as mentioned above. In an embodiment, the emitter emits monochromatic light.

According to an embodiment, the receiver comprises at least one avalanche photodiode, APD.

The receiver can comprise more than one photodiode. For example, the receiver comprises an array of photodiodes. An avalanche photodiode is a type of semiconductor photodetector that uses the avalanche effect to amplify the signal generated by incident electromagnetic radiation. When a photon is absorbed by the APD, it creates an electron-hole pair. Under certain conditions, these carriers can be accelerated by a high electric field, which results in additional carrier generation through impact ionization. This process causes an avalanche of carriers, leading to an amplification of the original signal. In particular, the receiver comprises at least one single-photon avalanche diode, SPAD. A SPAD refers to an avalanche diode that is operated in Geiger mode, i.e. above the breakdown voltage. The avalanche process leads to a large output pulse for each detected photon. SPADs offer several advantages over other detectors capable of detecting photons, including high sensitivity, high time resolution, low noise rate and low dark current rate. The optical sensor may additionally include electronics to enable the full SPAD operation (bias voltage, quench circuit etc.).

According to an embodiment, the optoelectronic device further comprises a clock generator circuit, wherein the clock generator circuit is configured to provide a timing signal to the emitter for generation of periodic pulses of primary electromagnetic radiation.

The clock generator circuit may be electrically connected to the emitter, e.g. by means of electric interconnections. The emitter and the clock generator circuit may be arranged in or on a common substrate, e.g. semiconductor substrate or printed circuit board. By means of the clock generator circuit providing the timing signal the emitter can be switched on and off in a rapid, periodic manner in order to produce pulses of primary electromagnetic radiation. The resulting pulse duration can be as short as possible and, for example, not more than 10% longer than the lifetime of excitons of the conversion layer, i.e. the time period in which an electron-hole pair recombines. This can ensure that a random number of photons are emitted from the conversion layer during an illumination cycle. For example, the lifetime of excitons is 15 ns, 20 ns or 25 ns. The pulse duration may be shorter than the lifetime.

According to an embodiment of the optoelectronic device, the conversion layer is arranged on a radiation emitting surface of the emitter.

The radiation emitting surface of the emitter is the surface from which the primary electromagnetic radiation propagates. That the conversion layer is arranged on the radiation emitting surface can mean that it is in direct physical contact with the radiation emitting surface. For example, the conversion layer is directly deposited on the radiation emitting surface of the emitter. As mentioned above, the conversion layer may be implemented as cover layer that is deposited on the emitter or on an emitter module. Because the conversion layer is applied directly to the emitter, the primary electromagnetic radiation can be efficiently absorbed. Further, the size of the optoelectronic device can be reduced. Advantageously, no optical elements like lenses are required to focus or redirect the primary electromagnetic radiation.

According to an embodiment of the optoelectronic device, the filter layer is arranged on a radiation receiving surface of the receiver.

The radiation receiving surface of the receiver is the surface at which the secondary electromagnetic radiation penetrates the receiver. That the filter layer is arranged on the radiation receiving surface can mean that it is in direct physical contact with the radiation receiving surface. For example, the filter layer is directly deposited on the radiation receiving surface of the receiver. The filter layer may be implemented as cover that is deposited on the receiver or on a receiver module. Because the filter layer is applied directly to the receiver, the primary electromagnetic radiation can be efficiently blocked and prevented from reaching the receiver. Thus, only the secondary electromagnetic radiation can reach the receiver. Further, the size of the optoelectronic device can be reduced. No optical elements like lenses are required to focus or redirect the secondary electromagnetic radiation.

According to an embodiment of the optoelectronic device, the emitter, the conversion layer and the receiver are arranged on or above each other, such that the radiation emitting surface of the emitter faces the radiation receiving surface of the receiver and the conversion layer is arranged between the emitter and the receiver.

This can mean that the components of the optoelectronic device are arranged in a stacked manner. In other words, the emitter, the conversion layer and the receiver are arranged on top of each other in a direction, which runs parallel to the direction in which the primary electromagnetic radiation is emitted by the emitter. For example, the conversion layer is arranged on the emitter, the filter layer is arranged on the conversion layer and the receiver is arranged on the filter layer. Further, optional adjustment layers can be arranged between at least some of these components in order to match the refractive indices of the components and to avoid light refraction. The emitter can be arranged on a substrate, in or on which also the clock generator circuit is arranged. The receiver can be arranged on a further substrate, in or on which also the controller is arranged. Such a stack may be integrally formed. By such an arrangement light paths are shortened and light scattering and reflections can be reduced. Further, the optoelectronic device can be very compact.

According to an embodiment of the optoelectronic device, the emitter and the receiver are arranged on a substrate, and the conversion layer is arranged above the substrate.

This can mean that the emitter and the receiver are arranged on a common substrate, on or in which also the controller and/or the clock generator circuit are arranged. In this way, an assembly can be simplified because all electrical components are arranged and interconnected on a common substrate. The substrate can be, for example, a semiconductor substrate, on which at least one of the emitter, the receiver, the controller and the clock generator circuit is monolithically integrated. It is also possible that the substrate is a printed circuit board, PCB, or the like. In this embodiment the conversion layer is arranged above the substrate, such that it can be illuminated by primary electromagnetic radiation by the emitter and it can emit secondary electromagnetic radiation towards the receiver. For example, the conversion layer is arranged on an inner side of a housing enclosing the substrate with the emitter and the receiver.

Further, an optoelectronic system is provided. The optoelectronic system comprises the optoelectronic device as described above. This means that all features disclosed for the optoelectronic device are also disclosed for the optoelectronic system and vice versa.

In an embodiment, the optoelectronic system comprises the optoelectronic device according to one of the above described embodiments and at least one further optoelectronic device according to one of the above described embodiments. According to an embodiment, the optoelectronic system further comprises a signal combiner configured to combine the respective sequences of random numbers generated by the optoelectronic device and the further optoelectronic device.

The optoelectronic system can be, for example, a personal computer, a smartphone, or any other electronic device which requires random numbers with high bandwidth. The optoelectronic system may comprise at least two optoelectronic devices according to one of the above embodiment. Thus, a bandwidth for generating random numbers can be increased. The rate of generating numbers in the sequence of random numbers can be increased. The signal combiner can combine the respective sequences of random numbers generated by the optoelectronic device and the further optoelectronic device to form a single sequence of random numbers.

Instead of using multiple optoelectronic devices it is also possible to increase the rate of generating random numbers by means of a single optoelectronic device which comprises a plurality of emitters and receivers, wherein each emitter is assigned to a respective receiver and wherein a respective conversion layer converts primary electromagnetic radiation emitted by the emitters into secondary electromagnetic radiation. Each receiver may be coupled to a respective controller, as mentioned above.

Further, a method of generating a sequence of random numbers is provided. The method of generating the sequence of random numbers can preferably be employed by the optoelectronic device or the optoelectronic system described above. This means that all features disclosed for the method are also disclosed for the optoelectronic device/system and vice versa.

According to an embodiment, the method of generating a sequence of random numbers comprises providing an emitter, a conversion layer and a receiver. The emitter, the conversion layer and the receiver are explained above. In a preferred embodiment, the conversion layer comprises a quantum dot material.

The method further comprises emitting, by the emitter, pulses of primary electromagnetic radiation. The method further comprises absorbing, by the conversion layer, the primary electromagnetic radiation. The method further comprises emitting, by the conversion layer, secondary electromagnetic radiation in response to the absorbing. The method further comprises receiving, by the receiver, the secondary electromagnetic radiation. The method further comprises evaluating with each pulse of primary electromagnetic radiation whether an amount of secondary electromagnetic radiation received by the receiver exceeds a predetermined threshold value. The method further comprises appending a number associated with a result of the evaluating to the sequence of random numbers.

Evaluating whether an amount of secondary electromagnetic radiation received by the receiver exceeds a predetermined threshold value and appending a number associated with a result of the evaluating to the sequence of random numbers can be performed by a controller, as explained above.

A certain number of photons of primary electromagnetic radiation is absorbed by the conversion layer and converted into an electron-hole pair. After some time the electron and hole will recombine radiatively, i.e. under emitting photons of secondary electromagnetic radiation. In other words, the conversion layer converts primary electromagnetic radiation emitted by the emitter into secondary electromagnetic radiation to be received by the receiver. However, the conversion is based on randomness, at least to some extent.

This is because the manner of recombination (radiatively or non-radiatively) is a source of randomness. The amount of time required for the recombination process to occur is an inherently random value for each electron-hole pair. Additionally, the direction of the emitted photon of secondary electromagnetic radiation is inherently random. Because not every emitted photon will reach the receiver this also provides a source of randomness in the exact number of photons which reach the receiver. Thus, a method of generating true random numbers with very high bandwidth is provided. The emitter, the conversion layer, and the receiver (and the controller) can be arranged in a very compact way, so that, if adequately miniaturized, it fits in an extremely small package. Further, the emitter can be pulsed in a rapid, periodic manner. The emitter, the receiver and the controller can be based on standard semiconductor manufacturing techniques, and these components do not require high power consumption. Thus, the hardware required for the method of generating random numbers can have a tiny form-factor with extremely low power consumption.

According to an embodiment of the method, emitting pulses of primary electromagnetic radiation comprises providing a timing signal to the emitter for generating periodic pulses of primary electromagnetic radiation. For example, the timing signal is provided to the emitter by means of clock generator circuit, as explained above. The timing signal, and thus the pulse duration of primary electromagnetic radiation, can be tuned to the lifetime of excitons of the conversion layer.

This can mean that the pulse duration can be shorter than the lifetime of electron-hole pairs in the conversion layer generated by the primary electromagnetic radiation. This can ensure that a random number of photons are emitted from the conversion layer during an illumination cycle.

According to an embodiment of the method, receiving secondary electromagnetic radiation comprises preventing electromagnetic radiation, apart from at least a portion of the secondary electromagnetic radiation, from reaching the receiver. For example, this can be achieved by means of a filter layer arranged between the conversion layer and the receiver. The filter layer can be such that it rejects photons of all energies emitted by the emitter and allows photons of the energies emitted by the conversion layer to pass. Because only secondary electromagnetic radiation can reach the receiver, a measurement is more accurate and the primary radiation cannot falsify the measurement result. Thus, the generation of random numbers is not biased.

Further embodiments of the method become apparent to the skilled reader from the embodiments of the optoelectronic device described above.

### BRIEF DESCRIPTION OF THE DRAWINGS

The following description of figures may further illustrate and explain aspects of the optoelectronic device, the optoelectronic system and the method of generating a sequence of random numbers. Components and parts of the optoelectronic device that are functionally identical or have an identical effect are denoted by identical reference symbols. Identical or effectively identical components, parts and steps might be described only with respect to the figures where they occur first. Their description is not necessarily repeated in successive figures.

FIG. 1 shows an optoelectronic device according to an embodiment.

FIG. 2 shows an optoelectronic device according to another embodiment.

FIG. 3 shows an optoelectronic device according to another embodiment.

FIG. 4 shows the determination of a threshold value used for the generation of a sequence of random numbers.

FIG. 5 shows an optoelectronic system according to an embodiment.

FIG. 6 schematically shows a method of generating a sequence of random numbers according to an embodiment.

### DETAILED DESCRIPTION

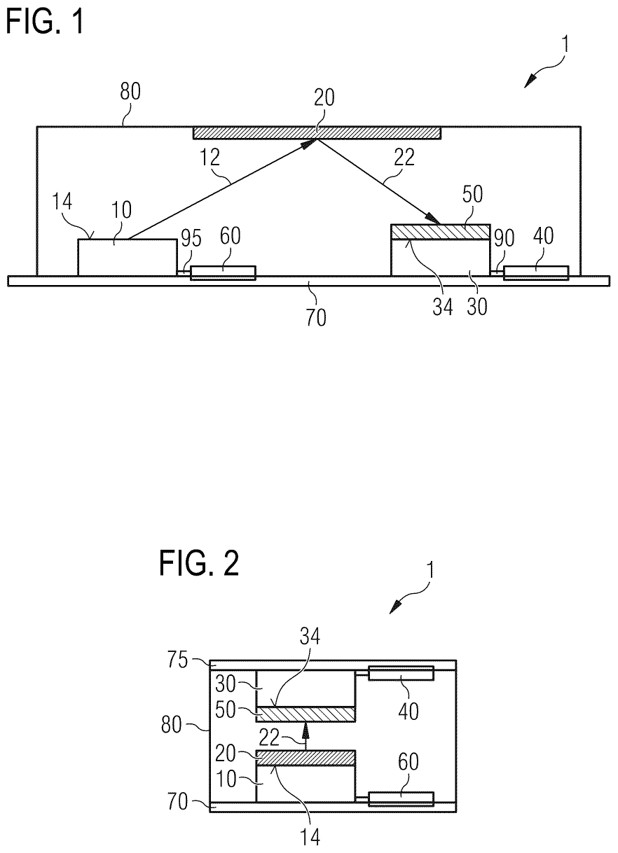

In FIG. 1 an optoelectronic device 1 according to an embodiment is shown. The optoelectronic device 1 is configured to generate a sequence of random numbers. It comprises an emitter 10 configured to emit pulses of primary electromagnetic radiation 12 during operation. It further comprises a conversion layer 20 configured to absorb the primary electromagnetic radiation 12 and to emit secondary electromagnetic radiation 22 in response to the absorption.

The optoelectronic device 1 further comprises a receiver 30 configured to receive the secondary electromagnetic radiation 22. The optoelectronic device 1 further comprises a controller 40 which is coupled to the receiver 30. The controller 40 is configured to evaluate with each pulse of primary electromagnetic radiation 12 whether an amount of secondary electromagnetic radiation 22 received by the receiver 30 exceeds a predetermined threshold value Vth and to append a number associated with a result of the evaluation to the sequence of random numbers.

The emitter 10 can comprise a light emitting diode, LED, or a laser diode. The receiver 30 can comprise a photodiode, in particular an avalanche photodiode or single-photon avalanche diode. The conversion layer 20 can comprises a quantum dot material, in particular made of semiconductor nanocrystals.

In the embodiment according to FIG. 1, the emitter 10 and the receiver 30 are arranged on a common substrate 70. For example, the substrate 70 is a semiconductor substrate 70, on which the emitter 10 and/or the receiver 30 can be monolithically integrated. It is further possible that the substrate is implemented as printed circuit board, PCB. In that case the emitter 10 and the receiver 30 can be deposited on a main surface of the PCB, for example by means of soldering. Thus, in the embodiment according to FIG. 1, the emitter 10 and the receiver 30 are in the same plane and adjacent to each other. A light barrier (not shown) can be arranged in between in order to prevent primary electromagnetic radiation 12 emitted by the emitter 10 to directly propagate towards the receiver 30.

The controller 40 can also be arranged in or on the substrate 70. For example, if the substrate 70 is a semiconductor substrate 70, the controller 40 can be implemented as integrated circuit in the semiconductor substrate 70. It is also possible that the controller 40 is implemented as separate chip or as part of a receiver/detector chip. The controller 40 is electrically connected to the receiver 30 by means of electrical interconnections 90, which can be arranged in or on the substrate 70.

The optoelectronic device 1 according to FIG. 1 further comprises a clock generator circuit 60. The clock generator circuit 60 can also be arranged in or on the substrate 70. For example, if the substrate 70 is a semiconductor substrate 70, the clock generator circuit 60 can be implemented as integrated circuit in the semiconductor substrate 70. It is also possible that the clock generator circuit 60 is implemented as separate chip or as part of an emitter chip. The clock generator circuit 60 is electrically connected to the emitter 10 by means of electrical interconnections 95, which can be arranged in or on the substrate 70.

The optoelectronic device 1 may comprise further components for its operation. For example, the optoelectronic device 1 may comprise a driver circuit providing a driving current to the emitter 10. It may further comprise a power supply for the receiver 30. Such components are omitted in FIG. 1.

The embodiment according to FIG. 1 further comprises a housing 80. The housing is arranged on the main surface of the substrate 70 and encloses the emitter 10, the receiver 30, the controller 40 and the clock generator circuit 60. The housing 80 can comprise a light absorbing material. This can mean that the housing 80 does not comprise a light reflecting material. Thus, primary electromagnetic radiation 12 emitted by the emitter 10 is not reflected by the housing 80, so that variable light path lengths are avoided. A cavity is formed by the substrate 70 and the housing 80. The cavity may be filled with gas/air or vacuum.

The conversion layer 20 is arranged above the substrate 70. It may be deposited on an inner side of the housing 80. In particular, it may be arranged on a ceiling of the housing 80, wherein the ceiling faces the emitter 10 and the receiver 30 on the main surface of the substrate 70. The primary electromagnetic radiation 12 emitted by the emitter 10 propagates from a radiation emitting surface 14 of the emitter 10 towards the conversion layer 20. At least a portion of the primary electromagnetic radiation 12 reaches the conversion layer 20. There, the primary electromagnetic radiation 12 is converted by the conversion layer 20 into secondary electromagnetic radiation 22. The conversion takes place by means of luminescence, in particular by means of a luminescent quantum dot material. The secondary electromagnetic radiation 22 propagates from the conversion layer 20 towards the receiver 30, where at least a portion of the secondary electromagnetic radiation 22 arrives. The receiver 30 may comprise a photodetector, in particular a photodiode, which converts the secondary electromagnetic radiation 22 into an output voltage or output current. The amount of secondary electromagnetic radiation 22 received by the receiver 30, i.e. the output voltage/current, is evaluated by the controller 40 and compared to the threshold value Vth. Alternatively, the receiver 30 comprises a SPAD, and the controller 40 counts the photons of secondary electromagnetic radiation 22 received by the receiver 30 and compares the photon count to the threshold value Vth.

The optoelectronic device 1 according to FIG. 1 further comprises a filter layer 50. The filter layer 50 is arranged on a radiation receiving surface 34 of the receiver 30. Thus, it is arranged between the conversion layer 20 and the receiver 30. The filter layer 50 is configured to block electromagnetic radiation apart from at least a portion of the secondary electromagnetic radiation 22. This can mean that the filter layer 50 is configured to block primary electromagnetic radiation 12 emitted by the emitter 10. Thus, only photons of secondary electromagnetic radiation may be allowed to reach the receiver 30.

In FIG. 2 an optoelectronic device 1 according to another embodiment is shown. The embodiment according to FIG. 2 is different from the embodiment according to FIG. 1 in that the receiver 30 (with the controller 40) is not arranged in the same plane as the emitter 10 (with the clock generator circuit 60). Instead, the receiver 30 and the emitter 10 are arranged on top of each other, i.e. in a stacked arrangement. The emitter 10 (with the clock generator circuit 60) is arranged on the substrate 70, and the receiver 30 (with the controller 40) is arranged on a further substrate 75, such that the emitter 10 and the receiver 30 face each other. In the embodiment of FIG. 2, the conversion layer 20 is deposited on the radiation emitting surface 14 of the emitter 10 between the emitter 10 and the receiver 30. The filter layer 50 is deposited on the radiation receiving surface 34 of the receiver 30 between the conversion layer 20 and the receiver 30. There is a gap between the filter layer 50 and the conversion layer 20. The substrate 70, the further substrate 75 and the housing 80 delineate a cavity. The cavity (including the gap) can be filled with air/gas or vacuum.

Since the conversion layer 20 is directly arranged on the emitter 10, primary electromagnetic radiation 12 (not shown in FIG. 2) emitted by the emitter 10 is directly converted into secondary electromagnetic radiation 22 by the conversion layer 20. Secondary electromagnetic radiation 22 emitted by the conversion layer 20 propagates through the gap and the filter layer 50 towards the receiver 20.

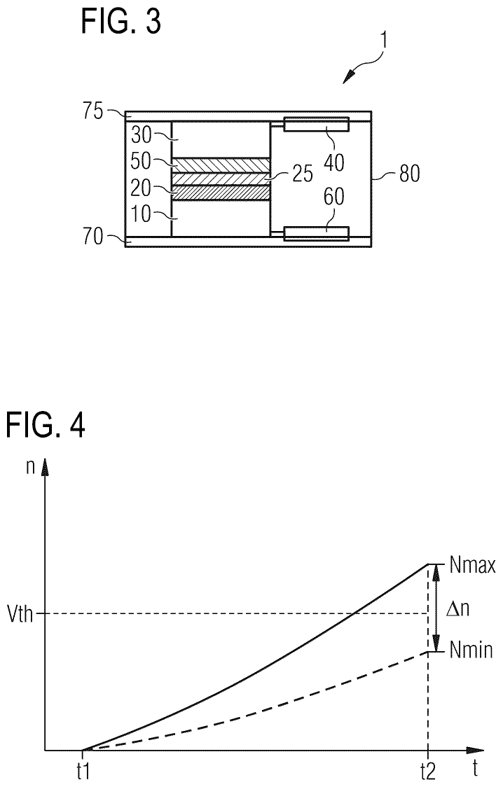

In FIG. 3 an optoelectronic device 1 according to another embodiment is shown. The embodiment according to FIG. 3 is different from the embodiment according to FIG. 2 in that there is no air gap between the conversion layer 20 and the filter layer 50. Instead, the emitter 10, the conversion layer 20, the filter layer 50 and the receiver 30 are implemented as an integrally formed stack. However, there might be optional adjustment layers 25 between at least some of these components. The adjustment layers 25 are configured to match the refractive indices of the components. In the shown example there is one adjustment layer 25 arranged between the conversion layer 20 and the filter layer 50. The optoelectronic device 1 may comprise further adjustment layers 25 (not shown), for example between the emitter 10 and the conversion layer 20, or between the filter layer 50 and the receiver 30.

FIG. 4 shows how the threshold value Vth can be obtained. FIG. 4 shows the number of detected photons n at the receiver 30 as function of the pulse time t. Because not all atoms/quantum dots (QD) of the conversion layer 20 are excited during the primary electromagnetic radiation pulse, not all excited atoms/QDs will emit a photon during recombination, and because those emitted photons travel in a random direction, the number of photons of secondary electromagnetic radiation 22 at the receiver varies from pulse to pulse. The probabilistic spread between the minimum Nmin and maximum number Nmax of photons counted per pulse can be determined by the properties of the components. FIG. 4 shows a pulse start time t1 and a pulse end time t2. The dashed line shows the minimum number Nmin of photons detected during that pulse time. The solid line shows the maximum number Nmax of photons detected during that pulse time. Thus, there is a range Δn of detected photons at the end t2 of each pulse. The actual number of detected photons lies within that range Δn. If the threshold number Vth is selected within this range Δn, random numbers can be generated by comparing the actual number n of detected photons to the threshold value Vth. For example, the threshold value Vth is selected to be in the center of the range Δn, that means in the middle between the minimum number Nmin and maximum number Nmax of detectable photons.

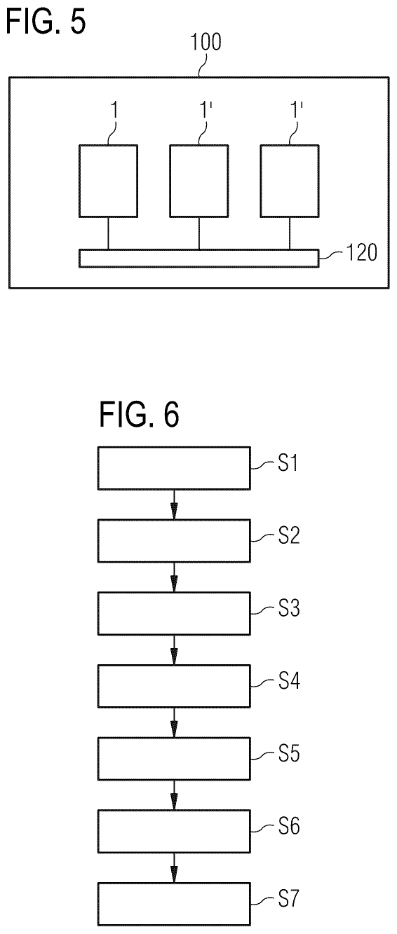

In FIG. 5 an optoelectronic system 100 according to an embodiment is shown. The optoelectronic system 100 comprises the optoelectronic device 1. The optoelectronic system further comprises at least one further optoelectronic device 1′. In the shown example the optoelectronic system 100 comprises two further optoelectronic devices 1′. The optoelectronic device 1 and the two further optoelectronic devices 1′ are coupled to a signal combiner 120. The signal combiner 120 is configured to combine the respective sequences of random numbers generated by the optoelectronic device 1 and the further optoelectronic devices 1′. Thus, a rate of generating random numbers and/or sequences of random numbers can be increased.

With FIG. 6 an exemplary embodiment of the method of generating a sequence of random numbers is described. The method comprises the following steps that are not necessarily carried out in this order but can be carried out in this order.

In a first step S1, an emitter 10, a conversion layer 20 and a receiver 30 are provided. The emitter 10 can be an LED. The conversion layer 20 can comprise a quantum dot material. The receiver 30 can comprise a photodiode, in particular a SPAD.

In a second step S2, pulses of primary electromagnetic radiation 12 are emitted by the emitter 10. Emitting pulses of primary electromagnetic radiation 12 may comprise providing a timing signal to the emitter 10 for generating periodic pulses of primary electromagnetic radiation 12.

In a third step S3, the primary electromagnetic radiation 12 is absorbed by the conversion layer 20. At least a portion of primary electromagnetic radiation 12 is absorbed by the conversion layer 20. By means of the absorption, the primary electromagnetic radiation generates electron-hole pairs in the conversion layer. Thus, the conversion layer 20 is placed in an excited state.

In a fourth step S4, secondary electromagnetic radiation 22 is emitted by the conversion layer 20 in response to the absorbing. At least a portion of the electron-hole pairs in the conversion layer 20 recombines under emission of secondary electromagnetic radiation 22. Thus, the conversion layer 20 emits photons as it transitions to its ground state.

In a fifth step S5, the secondary electromagnetic radiation 22 is received by the receiver 30. At least a portion of the secondary electromagnetic radiation 22 emitted by the conversion layer 20 is received by the receiver 30. The fifth step S5 may further comprise preventing electromagnetic radiation, apart from at least a portion of the secondary electromagnetic radiation 22, from reaching the receiver 30. In particular, primary electromagnetic radiation 12 emitted by the emitter 10 is blocked.

In a sixth step S6, it is evaluated with each pulse of primary electromagnetic radiation 12 whether an amount of secondary electromagnetic radiation 22 received by the receiver 30 exceeds a predetermined threshold value Vth. The result of this evaluation is based on randomness, since not all electron-hole pairs recombine radiatively, and the time required for the recombination process and the direction of the emitted photon of secondary electromagnetic radiation is inherently random.

In a seventh step S7, a number associated with the result of the evaluating is appended to the sequence of random numbers. For example, a “0” (i.e. “FALSE”) is appended if the amount of secondary electromagnetic radiation 22 received by the receiver 30 does not exceed the predetermined threshold value Vth. A “1” (i.e. “TRUE”) is appended if the amount of secondary electromagnetic radiation 22 received by the receiver 30 equals or exceeds the predetermined threshold value Vth.

The embodiments of the optoelectronic device 1, the optoelectronic system 100 and the method of generating a sequence of random numbers disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

### REFERENCES

1 optoelectronic device
10 emitter
12 primary electromagnetic radiation
14 radiation emitting surface
20 conversion layer
22 secondary electromagnetic radiation
30 receiver
34 radiation receiving surface
40 controller
50 filter layer
60 clock generator circuit
70 substrate
75 further substrate
80 housing
90, 95 electric interconnection
100 optoelectronic system
120 signal combiner
n number of detected photons
Nmax maximum number of detectable photons
Nmin minimum number of detectable photons
S1-S7 steps
t, t1, t2 time
Vth threshold value

1. An optoelectronic device for generating a sequence of random numbers, comprising:
an emitter configured to emit pulses of primary electromagnetic radiation during operation;
a conversion layer configured to absorb the primary electromagnetic radiation and to emit secondary electromagnetic radiation in response to the absorption;
a receiver (30) configured to receive the secondary electromagnetic radiation; and
a controller coupled to the receiver, the controller being configured to evaluate with each pulse of primary electromagnetic radiation whether an amount of secondary electromagnetic radiation received by the receiver exceeds a predetermined threshold value and to append a number associated with a result of the evaluation to the sequence of random numbers.

2. The optoelectronic device according to claim 1, wherein the conversion layer comprises a quantum dot material.

3. The optoelectronic device according to claim 1, wherein the conversion layer comprises semiconductor nanocrystals.

4. The optoelectronic device according to claim 1, further comprising a filter layer being arranged between the conversion layer and the receiver, wherein the filter layer is configured to block electromagnetic radiation apart from at least a portion of the secondary electromagnetic radiation.

5. The optoelectronic device according to claim 1, wherein the emitter comprises at least one light emitting diode, LED, or at least one laser diode.

6. The optoelectronic device according to claim 1, wherein the receiver comprises at least one avalanche photodiode, APD, in particular at least one single-photon avalanche diode, SPAD.

7. The optoelectronic device according to claim 1, further comprising a clock generator circuit, wherein the clock generator circuit is configured to provide a timing signal to the emitter for generation of periodic pulses of primary electromagnetic radiation.

8. The optoelectronic device according to claim 1, wherein the conversion layer is arranged on a radiation emitting surface of the emitter.

9. The optoelectronic device according to claim 4, wherein the filter layer is arranged on a radiation receiving surface of the receiver.

10. The optoelectronic device according to claim 1, wherein the emitter, the conversion layer and the receiver are arranged on or above each other, such that a radiation emitting surface of the emitter faces a radiation receiving surface of the receiver and the conversion layer is arranged between the emitter and the receiver.

11. The optoelectronic device according to claim 1, wherein the emitter and the receiver are arranged on a substrate, and wherein the conversion layer is arranged above the substrate.

12. An optoelectronic system, comprising:
the optoelectronic device according to claim 1;
at least one further optoelectronic device according to claim 1; and
a signal combiner (120) configured to combine the respective sequences of random numbers generated by the optoelectronic device and the further optoelectronic device.

13. A method of generating a sequence of random numbers, the method comprising:
providing an emitter, a conversion layer, and a receiver;
emitting, by the emitter, pulses of primary electromagnetic radiation;
absorbing, by the conversion layer, the primary electromagnetic radiation;
emitting, by the conversion layer, secondary electromagnetic radiation in response to the absorbing;
receiving, by the receiver, the secondary electromagnetic radiation;
evaluating with each pulse of primary electromagnetic radiation whether an amount of secondary electromagnetic radiation received by the receiver exceeds a predetermined threshold value; and
appending a number associated with a result of the evaluating to the sequence of random numbers.

14. The method according to claim 13, wherein emitting pulses of primary electromagnetic radiation comprises providing a timing signal to the emitter for generating periodic pulses of primary electromagnetic radiation.

15. The method according to claim 13, wherein receiving secondary electromagnetic radiation comprises preventing electromagnetic radiation, apart from at least a portion of the secondary electromagnetic radiation, from reaching the receiver.

16. The optoelectronic device according to claim 1, wherein the predetermined threshold value is determined by calibration prior to normal operation of the optoelectronic device and is based on a probabilistic range of photons reaching the receiver during each cycle.

17. The method according to claim 13, wherein evaluating whether an amount of secondary electromagnetic radiation exceeds a predetermined threshold value comprises determining an output voltage or output current of the receiver and comparing the output voltage with a predetermined threshold voltage or comparing the output current with a predetermined threshold current.

18. An optoelectronic device for generating a sequence of random numbers, comprising:
an emitter configured to emit pulses of primary electromagnetic radiation during operation;
a conversion layer configured to absorb the primary electromagnetic radiation and to emit secondary electromagnetic radiation in response to the absorption;
a receiver configured to receive the secondary electromagnetic radiation;
a controller coupled to the receiver, the controller being configured to evaluate with each pulse of primary electromagnetic radiation whether an amount of secondary electromagnetic radiation received by the receiver exceeds a predetermined threshold value and to append a number associated with a result of the evaluation to the sequence of random numbers; and
a clock generator circuit, wherein the clock generator circuit is configured to provide a timing signal to the emitter for generation of periodic pulses of primary electromagnetic radiation.
